(19) United States
(12) Patent Application Publication
(10) Pub. No.: US 2024/0280727 A1
(43) Pub. Date: Aug. 22, 2024

(54) PHOTOSENSITIVE COLORING COMPOSITIONS FOR INFRARED PASS FILTERS, INFRARED PASS FILTERS, METHODS OF PRODUCING PHOTOSENSITIVE COLORING COMPOSITIONS FOR INFRARED PASS FILTERS, AND METHODS OF PRODUCING INFRARED PASS FILTERS

(71) Applicant: TOPPAN HOLDINGS INC., Tokyo (JP)

(72) Inventors: Tetsuya HIROTA, Taito-ku (JP); Tadatoshi MAEDA, Taito-ku (JP)

(73) Assignee: TOPPAN HOLDINGS INC., Tokyo (JP)

(21) Appl. No.: 18/650,397

(22) Filed: Apr. 30, 2024

Related U.S. Application Data
(63) Continuation of application No. PCT/JP2022/041072, filed on Nov. 2, 2022.

(30) Foreign Application Priority Data
Nov. 2, 2021 (JP) 2021-179306

(51) Int. Cl. G02B 1/10; G02B 5/22

(52) U.S. Cl. CPC G02B 1/10; G02B 5/223

(57) ABSTRACT

A photosensitive coloring composition for an infrared pass filter contains a colorant, a polymerizable compound, a photopolymerization initiator, and a polymerization inhibitor. The polymerizable compound contains a first (meth)acrylate with two or more functional groups, at least one of the two or more functional groups being an amino group. A percentage of a mass of the first (meth)acrylate relative to a mass of the photopolymerization initiator is 50% or greater and 500% or less. A percentage of a mass of the polymerization inhibitor relative to a mass of the photopolymerization initiator is 3% or greater and 30% or less.

### CROSS-REFERENCE TO RELATED APPLICATIONS

The present application is a continuation of and claims the benefit of priority to International Application No. PCT/JP2022/041072, filed Nov. 2, 2022, which is based upon and claims the benefit of priority to Japanese Application No. 2021-179306, filed Nov. 2, 2021. The entire contents of these applications are incorporated herein by reference.

### BACKGROUND OF THE INVENTION

### Field of the Invention

The present invention relates to photosensitive coloring compositions for infrared pass filters, infrared pass filters, methods of producing photosensitive coloring compositions for infrared pass filters, and methods of producing infrared pass filters.

### Description of Background Art

Examples of the colorants contained in the infrared pass filters include bisbenzofuranone-based pigments, azomethine-based pigments, perylene-based pigments and azo-based dyes (see e.g., JP 2016-177273 A and JP 2018-119077 A). The entire contents of these publications are incorporated herein by reference.

### SUMMARY OF THE INVENTION

According to one aspect of the present invention, a photosensitive coloring composition for an infrared pass filter includes a colorant, a polymerizable compound, a photopolymerization initiator, and a polymerization inhibitor. The polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

According to another aspect of the present invention, an infrared pass filter includes a colorant, a polymerizable compound, a photopolymerization initiator, and a polymerization inhibitor. The polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

According to yet another aspect of the present invention, a method of producing a photosensitive coloring composition for an infrared pass filter includes mixing a colorant, a polymerizable compound, a photopolymerization initiator, and a polymerization inhibitor. The polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an exploded perspective view illustrating a structure of a solid-state image sensor according to an embodiment of the present invention;

FIG. 2 is a cross-sectional view illustrating a structure of an infrared pass filter;

FIG. 3 is a graph showing a relationship between a difference value and a first ratio when a pixel size is 1.4 μm; and

FIG. 4 is a graph showing a relationship between rectangularity and a first ratio when a pixel size is 1.4 μm.

### DETAILED DESCRIPTION OF THE EMBODIMENTS

Embodiments will now be described with reference to the accompanying drawings, wherein like reference numerals designate corresponding or identical elements throughout the various drawings.

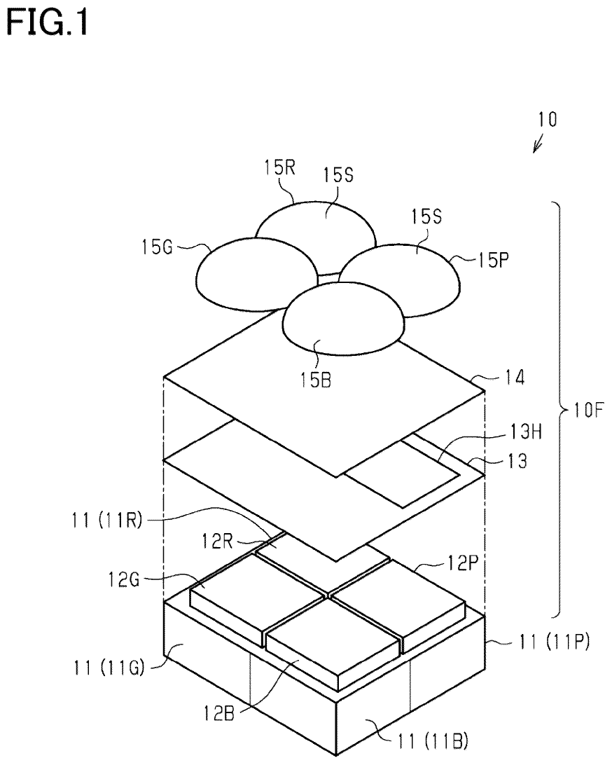

With reference to FIGS. 1 to 4, embodiments of a photosensitive coloring composition for an infrared pass filter, an infrared pass filter, a method of producing a photosensitive coloring composition for an infrared pass filter, and a method of producing an infrared pass filter will be described. In an embodiment of the present invention, infrared light is light having a wavelength in the range of 0.7 μm or more and 1 mm or less, and near-infrared light is light specifically having a wavelength in the range of 700 nm or more and 1,100 nm or less, of infrared light. Further, visible light is light having a wavelength in the range of 400 nm or more and 800 nm or less, and ultraviolet light is light having a wavelength in the range of 280 nm or more and less than 400 nm.

The infrared pass filter in the present disclosure refers to a filter having an average transmittance of 30% or less in the wavelength band of 400 nm or more and 800 nm or less and an average transmittance of 75% or greater in the wavelength band of 900 nm or more and 1,100 nm or less.

Further, in the present embodiment, (meth)acrylate means at least one of acrylate and methacrylate. Further, in the present embodiment, C.I. means color index.

### Solid-State Image Sensor

With reference to FIG. 1, a solid-state image sensor will be described. FIG. 1 is a schematic configuration diagram in which layers in part of a solid-state image sensor are separately illustrated.

As shown in FIG. 1, a solid-state image sensor 10 includes a solid-state image sensor filter 10F and multiple photoelectric conversion elements 11. The photoelectric conversion elements 11 include a red photoelectric conversion element 11R, a green photoelectric conversion element 11G, a blue photoelectric conversion element 11B and an infrared photoelectric conversion element 11P. The photoelectric conversion elements 11R, 11G and 11B for respective colors measure the intensity of visible light at specific wavelengths corresponding to the photoelectric conversion elements 11R, 11G and 11B, respectively. Each infrared photoelectric conversion element 11P measures the intensity of infrared light.

The solid-state image sensor 10 includes multiple red photoelectric conversion elements 11R, multiple green photoelectric conversion elements 11G, multiple blue photoelectric conversion elements 11B and multiple infrared photoelectric conversion elements 11P. FIG. 1 illustrates a repeating unit of the photoelectric conversion element 11 in the solid-state image sensor 10 for convenience of illustration.

The solid-state image sensor filter 10F includes multiple visible light filters, an infrared pass filter 12P, an infrared cut-off filter 13, a barrier layer 14, multiple visible light microlenses and an infrared microlens 15P.

The visible light color filters are composed of a red filter 12R, a green filter 12G and a blue filter 12B. The red filter 12R is disposed on a light-incident side of the red photoelectric conversion element 11R. The green filter 12G is disposed on a light-incident side of the green photoelectric conversion element 11G. The blue filter 12B is disposed on a light-incident side of the blue photoelectric conversion element 11B.

The respective color filters 12R, 12G and 12B may be formed directly on the photoelectric conversion elements 11R, 11G and 11B, respectively, as shown in FIG. 1, or a planarization layer may be disposed between the respective color filters 12R, 12G and 12B and the photoelectric conversion elements 11R, 11G and 11B. With this configuration, that is, by providing a planarization layer between the respective color filters 12R, 12G and 12B and the photoelectric conversion elements 11R, 11G and 11B, it is possible to enhance adhesion of the respective color filters 12R, 12G and 12B to the photoelectric conversion elements 11R, 11G and 11B.

The infrared pass filter 12P is disposed on a light-incident side of the infrared photoelectric conversion element 11P. The infrared pass filter 12P blocks the visible light which may otherwise be detected by the infrared photoelectric conversion element 11P to prevent it from reaching the infrared photoelectric conversion element 11P. This improves detection accuracy of infrared light by the infrared photoelectric conversion element 11P. The infrared light that may be detected by the infrared photoelectric conversion element 11P may be, for example, near-infrared light.

The thickness of the infrared pass filter 12P may be larger than the thickness of each of the color filters 12R, 12G and 12B. In this case, the infrared pass filter 12P can increase non-transparency to visible light.

The infrared cut-off filter 13 is disposed on a light-incident side of the color filters 12R, 12G and 12B. The infrared cut-off filter 13 has a through-hole 13H. The infrared pass filter 12P is located in a region defined by the through-hole 13H when viewed in a direction perpendicular to a plane in which the infrared cut-off filter 13 extends. On the other hand, the infrared cut-off filter 13 is located on the red filter 12R, the green filter 12G and the blue filter 12B when viewed in a direction perpendicular to a plane in which the infrared cut-off filter 13 extends.

The infrared cut-off filter 13 includes an infrared absorbing dye. The infrared absorbing dye has an infrared absorbance peak at wavelengths of near-infrared light.

Therefore, the infrared cut-off filter 13 can reliably absorb near-infrared light passing through the infrared cut-off filter 13. Accordingly, the infrared cut-off filter 13 sufficiently cuts off near-infrared light that may otherwise be detected by the photoelectric conversion elements 11 for respective colors. The infrared cut-off filter 13 can have a thickness of, for example, 300 nm or greater and 3 μm or less.

If an underlayer of the microlenses 15R, 15G, 15B and 15P has unevenness, the accuracy in processing the microlenses 15R, 15G, 15B and 15P may decrease. Therefore, in view of improvement in flatness of the underlayer of the microlenses 15R, 15G, 15B and 15P, the sum of the thickness of each of the color filters 12R, 12G and 12B and the thickness of the infrared cut-off filter 13 is preferably substantially equal to the thickness of the infrared pass filter 12P.

The infrared cut-off filter 13 may not necessarily have the through hole 13H. That is, the infrared cut-off filter 13 may be disposed on a light-incident side of the infrared pass filter 12P, in addition to the respective color filters 12R, 12G and 12B. In this case, the wavelength band of infrared light blocked by the infrared cut-off filter 13 for each filter is a first wavelength band, and the wavelength band of infrared light detected ty the infrared photoelectric conversion element 11P via the infrared pass filter 12P may be a second wavelength band. For example, the first wavelength band may be in the range of 700 nm or more and 900 nm or less, and the second wavelength band may be in the range of 900 nm or more and 1,100 nm or less. Accordingly, the infrared photoelectric conversion element 11P can efficiently detect near-infrared light.

The barrier layer 14 prevents oxidation sources from passing through the infrared cut-off filter 13. The oxidation source may be oxygen, water, or the like. The barrier layer 14 preferably has an oxygen transmission rate of, for example, 5.0 cc/m²/day/atm or less. The oxygen transmission rate is a value in accordance with JIS K 7126:2006. By setting the oxygen transmission rate to 5.0 cc/m²/day/atm or less, the barrier layer 14 prevents oxidation sources from reaching the infrared cut-off filter 13, whereby the infrared cut-off filter 13 is not likely to be oxidized by the oxidation sources. Accordingly, the light resistance of the infrared cut-off filter 13 can be enhanced.

The material forming the barrier layer 14 is an inorganic compound. The material forming the barrier layer 14 is preferably a silicon compound. The material forming the barrier layer 14 may be, for example, at least one of silicon nitride, silicon oxide and silicon oxynitride. That is, the material forming the barrier layer 14 may be any one of silicon nitride, silicon oxide and silicon oxynitride, or may be two or more of these.

The microlenses include the red microlens 15R, the green microlens 15G, the blue microlens 15B and the infrared microlens 15P. The red microlenses 15R are disposed on a light-incident side of the red filter 12R. The green microlenses 15G are disposed on a light-incident side of the green filter 12G. The blue microlenses 15B are disposed on a light-incident side of the blue filter 12B. The infrared microlens 15P is disposed on a light-incident side of the infrared pass filter 12P.

The microlenses 15R, 15G, 15B and 15P each have a light-incident surface 15S which is an outer surface. In order to collect light incident on the light-incident surface 15S toward the respective photoelectric conversion elements 11R, 11G, 11B and 11P, the microlenses 15R, 15G, 15B and 15P have a refractive index different from a refractive index of the outside air. The respective microlenses 15R, 15G, 15B and 15P contain a transparent resin.

### Method of Producing Solid-State Image Sensor Filter

In the method of producing a solid-state image sensor filter, first, respective color filters 12R, 12G and 12B are formed. The color filters 12R, 12G and 12B are each formed by forming a coating film containing a photosensitive coloring composition for each of the color filters 12R, 12G and 12B, and patterning the coating film by photolithography. For example, a coating film containing a red photosensitive composition is formed by applying a coating liquid containing a red photosensitive composition and drying the coating film. The red filter 12R is formed by exposure and development of the coating film containing the red photosensitive composition in a region corresponding to the red filter 12R. The green filter 12G and the blue filter 12B are also formed by the same method as for the red filter 12R.

Colorants contained in the photosensitive coloring compositions of the red filter 12R, the green filter 12G and the blue filter 12B may be organic pigments or inorganic pigments. The organic pigments and inorganic pigments may be used singly, or two or more organic pigments and inorganic pigments may be mixed. The pigments used as colorants are preferably organic pigments in view of high color development and high thermal resistance, especially high thermal decomposition resistance.

Examples of the organic pigments include phthalocyanine-based pigments, azo-based pigments, anthraquinone-based pigments, quinacridone-based pigments, dioxazine-based pigments, anthanthrone-based pigments, indanthrone-based pigments, perylene-based pigments, thioindigo-based pigments, isoindoline-based pigments, quinophthalone-based pigments and diketopyrrolopyrrole-based pigment.

The colorant used in the photosensitive coloring composition of the red filter 12R may be a red pigment. Examples of the red pigment include C.I. Pigment Red 7, 9, 14, 41, 48:1, 48:2, 48:3, 48:4, 81:1, 81:2, 81:3, 97, 122, 123, 146, 149, 168, 177, 178, 180, 184, 185, 187, 192, 200, 202, 208, 210, 215, 216, 217, 220, 223, 224, 226, 227, 228, 240, 246, 254, 255, 264, 272, C.I. Pigment Orange 36, 43, 51, 55, 59, 61, 71, 73, and the like.

In addition, the photosensitive coloring composition may further contain a pigment for toning, if necessary. Examples of the pigment for toning include C.I. Pigment Yellow 1, 2, 3, 4, 5, 6, 10, 12, 13, 14, 15, 16, 17, 18, 24, 31, 32, 34, 35, 35:1, 36, 36:1, 37, 37:1, 40, 42, 43, 53, 55, 60, 61, 62, 63, 65, 73, 74, 77, 81, 83, 93, 94, 95, 97, 98, 100, 101, 104, 106, 108, 109, 110, 113, 114, 115, 116, 117, 118, 119, 120, 123, 126, 127, 128, 129, 138, 139, 147, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 198, 199, 213, 214, and the like.

The colorant used in the photosensitive coloring composition of the green filter 12G may be a green pigment. Examples of the green pigment include C.I. Pigment Green 7, 10, 36, 37, 58, 59, and the like. The photosensitive coloring composition may further contain a pigment for toning, if necessary. Examples of the pigment for toning include C.I. Pigment Yellow 1, 2, 3, 4, 5, 6, 10, 12, 13, 14, 15, 16, 17, 18, 24, 31, 32, 34, 35, 35:1, 36, 36:1, 37, 37:1, 40, 42, 43, 53, 55, 60, 61, 62, 63, 65, 73, 74, 77, 81, 83, 93, 94, 95, 97, 98, 100, 101, 104, 106, 108, 109, 110, 113, 114, 115, 116, 117, 118, 119, 120, 123, 126, 127, 128, 129, 138, 139, 147, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 198, 199, 213, 214, and the like.

The colorant used in the photosensitive coloring composition of the blue filter 12B may be a blue pigment. Examples of the blue pigment include C.I. Pigment Blue 15, 15:1, 15:2, 15:3, 15:4, 15:6, 16, 22, 60, 64, 81, and the like. The blue pigment is preferably C.I. Pigment Blue 15:6.

The method of producing the infrared pass filter 12P includes the processes of preparing a photosensitive coloring composition, forming a coating film, and curing the coating film. The process of preparing a photosensitive coloring composition is performed by the method of preparing a photosensitive coloring composition for an infrared pass filter, which will be described later. The process of forming a coating film is performed by applying a coating liquid containing the photosensitive coloring composition to an object to be coated.

Specifically, the infrared pass filter 12P is produced, as with the red filter 12R, by forming a coating film containing a photosensitive coloring composition for an infrared pass filter and patterning the coating film by photolithography. The coating film is formed by applying a coating liquid containing the photosensitive composition for an infrared pass filter and drying the coating liquid. The infrared pass filter 12P is formed by exposure and development of the coating film in a region corresponding to the infrared pass filter 12P. The exposure of the coating film is performed using ultraviolet light. The ultraviolet light may be, for example, light having a wavelength of 365 nm.

The infrared cut-off filter 13 is produced by film formation using a liquid phase film formation method such as coating. The infrared cut-off filter 13 is made of a composition containing an infrared absorbing dye and a transparent resin. Examples of the infrared absorbing dye include anthraquinone-based dyes, cyanine-based dyes, phthalocyanine-based dyes, dithiol-based dyes, diimmonium-based dyes, squarylium-based dyes and croconium-based dyes. Examples of the transparent resin include acrylic resins, polyamide-based resins, polyimide-based resins, polyurethane-based resins, polyester-based resins, polyether-based resins, polyolefin-based resins, polycarbonate-based resins, polystyrene-based resins and norbornene-based resins.

In addition, the respective color photosensitive coloring compositions and the composition for the infrared cut-off filter 13 may further contain a binder resin, a photopolymerization initiator, a polymerization inhibitor, a polymerizable compound, an organic solvent, a leveling agent, and the like.

Furthermore, in patterning of the coating film by photolithography, it is preferred to use an exposure apparatus, such as a stepper, and a photomask having a predetermined pattern. After exposure of the coating film via the photomask, a developer can be used to remove the unexposed region of the coating film while remaining the exposed region to thereby pattern the coating film. The developer preferably exhibits alkalinity. The alkaline developer may be an inorganic alkaline developer or an organic alkaline developer. Examples of the inorganic alkaline developer include sodium hydroxide, potassium hydroxide, sodium carbonate, and the like. Examples of the organic alkaline developer include tetrahydroxyammonium compounds. Furthermore, the developer preferably contains a surfactant from the viewpoint of enhancing wettability of the developer to the coating film.

A barrier layer 14 is formed by film formation using a vapor phase film formation method such as sputtering, CVD or ion plating, or a liquid phase film formation method such as coating. A barrier layer 14 made of a silicon oxide may be formed by, for example, forming a film by sputtering using a target made of silicon oxide on a substrate on which the infrared cut-off filter 13 is formed. The barrier layer 14 made of a silicon oxide may be formed by, for example, forming a film by CVD using silane and oxygen on a substrate on which the infrared cut-off filter 13 is formed. The barrier layer 14 made of a silicon oxide may be formed by, for example, applying a coating liquid containing a polysilazane, modifying, and drying the coating film. The layer structure of the barrier layer 14 may be a single-layer structure made of a single compound, a laminate structure composed of layers made of a single compound, or a laminate structure composed of layers made of compounds different from each other.

The microlenses 15R, 15G, 15B and 15P are formed by forming a coating film containing a transparent resin, patterning the coating film by photolithography, and performing reflow by heat treatment. Examples of the transparent resin include acrylic resins, polyamide-based resins, polyimide-based resins, polyurethane-based resins, polyester-based resins, polyether-based resins, polyolefin-based resins, polycarbonate-based resins, polystyrene-based resins and norbornene-based resins.

### Infrared Pass Filter

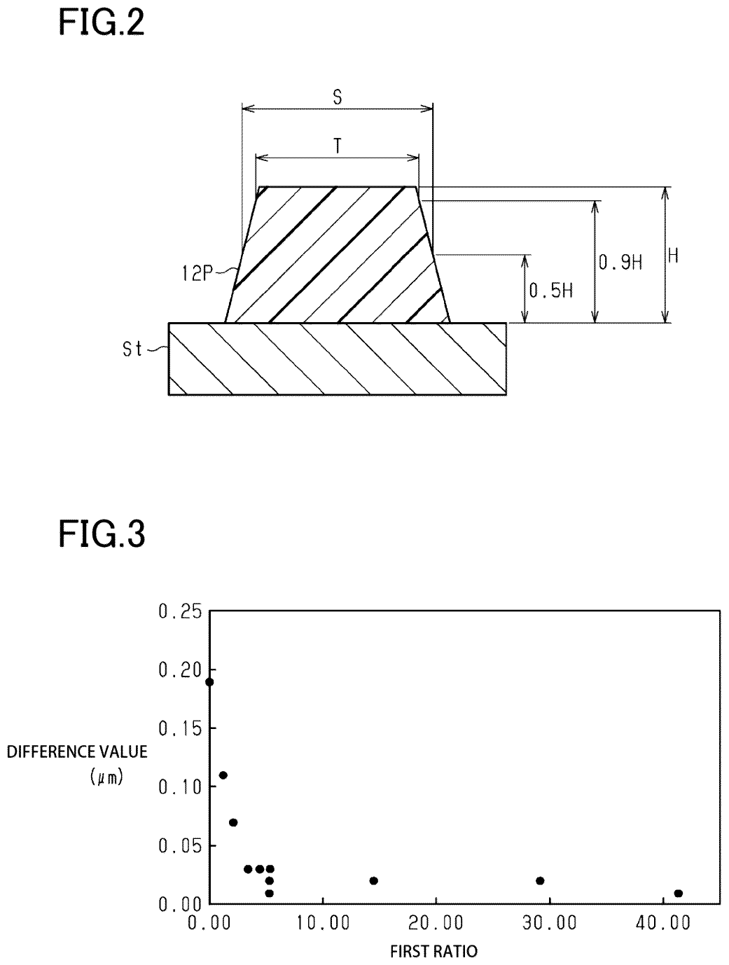

FIG. 2 shows a cross-sectional structure of the infrared pass filter 12P.

As shown in FIG. 2, the infrared pass filter 12P has a height H, in which 50% of the height H of the infrared pass filter 12P from a surface of a substrate St on which the infrared pass filter 12P is formed is a first height 0.5H. In the height H of the infrared pass filter 12P, 90% of the height H of the infrared pass filter 12P from the surface of the substrate St is a second height 0.9H. The width of the infrared pass filter 12P at the first height 0.5H is a first width S. The width of the infrared pass filter 12P at the second height 0.9H is a second width T.

A ratio (T/S) of the second width T to the first width S is preferably 0.75 or greater. The ratio of the second width T to the first width S of 0.75 or greater can cause the cross-section of the infrared pass filter 12P to have improved rectangularity, increasing the sensitivity of the infrared pass filter 12P. The ratio of the second width T to the first width S is preferably 1.0 or less. The ratio of the second width T to the first width S of 1.0 or less can prevent the cross-section of the infrared pass filter 12P from having a truncated pyramid shape, preventing a decrease in adhesion of the infrared pass filter 12P.

The infrared pass filter 12P may include two or more color layers. On the premise that the total thickness of the infrared pass filter 12P is the same, when the infrared pass filter 12P includes two or more color layers, the thickness of each layer can be reduced, increasing the adhesion of the color layer, compared with the case where the infrared pass filter 12P is composed of a single layer. The number of color layers may be, for example, 2 or more and 6 or less, and preferably 2 or more and 4 or less.

When the infrared pass filter 12P includes 2 or more color layers, all the color layers may be made of a photosensitive coloring composition having the same composition. Alternatively, 2 or more color layers may include a first layer made of a photosensitive coloring composition having a first composition, and a second layer made of a photosensitive coloring composition having a second composition. The second composition differs from the first composition. The infrared pass filter 12P may include a planarization layer located between the color layers. The planarization layer does not contain a colorant.

The total thickness of the infrared pass filter 12P, that is, the height H, may be 0.3 μm or greater and 5 μm or less, and preferably 0.5 μm or greater and 3 μm or less. The infrared pass filter 12P may have, for example, a square shape when viewed in a direction perpendicular to the surface of the substrate St. When viewed in a direction perpendicular to the surface of the substrate St, a side length of the infrared pass filter 12P, that is, a pixel size of the infrared pass filter 12P may be 0.7 μm or greater and 20 μm or less, and preferably 0.9 μm or greater and 5 μm or less.

### Photosensitive Coloring Composition for Infrared Pass Filter

The photosensitive coloring composition for an infrared pass filter (hereinafter, also referred to as a “photosensitive coloring composition”) includes a colorant, a polymerizable compound, a photopolymerization initiator, and a polymerization inhibitor. The polymerizable compound contains a first bi- or higher functional (meth)acrylate containing an amino group. A percentage of a mass of the first (meth)acrylate relative to a mass of the photopolymerization initiator is 50% or greater and 500% or less. That is, the polymerizable compound contains the first (meth)acrylate with two or more functional groups, at least one of the two or more functional groups being an amino group. In other words, the two or more functional groups include one or more amino groups.

A percentage of a mass of the polymerization inhibitor relative to a mass of the photopolymerization initiator is 3% or greater and 30% or less. The photosensitive coloring composition may contain a binder resin. The details of the photosensitive coloring composition will be described below.

The colorant may be a colorant that exhibits a black color. The colorant that exhibits a black color may be a colorant used singly to exhibit a black color. Alternatively, the colorant may contain two or more colorants that exhibit green, blue, red, yellow, violet, magenta, cyan, orange, and the like colors. The colorant may further contain an infrared absorbing dye. The colorant may be used singly or may contain two or more colorants as long as the colorant has transmission properties such that the infrared pass filter formed of the photosensitive coloring composition has an average transmittance of 30% or less in the wavelength band of 400 nm or more and 800 nm or less and an average transmittance of 75% or greater in the wavelength band of 900 nm or more and 1,100 nm or less.

Further, the colorant may have an average transmittance of less than 10% in the wavelength band of 280 nm or more and less than 400 nm. In exposure of the photosensitive coloring composition, the coating film containing the photosensitive coloring composition is irradiated with ultraviolet light, that is, light having the wavelength of 280 nm or more and less than 400 nm. Since the colorant has a low average transmittance to ultraviolet light, polymerization reaction of the polymerizable compound by the photopolymerization initiator is less likely to occur when the coating film is irradiated with ultraviolet light. On the other hand, the colorants contained in the photosensitive coloring compositions for producing respective color filters, for example, a coloring composition for red, a coloring composition for green and a coloring composition for blue, have an average transmittance of 10% or greater in the wavelength band of 280 nm or more and less than 400 nm. Accordingly, since the photosensitive compositions for producing respective color filters have high average transmittance to ultraviolet light, polymerization reaction of the polymerizable compound by the photopolymerization initiator is more likely to occur compared with the photosensitive coloring composition for an infrared pass filter.

Examples of the colorant used singly to exhibit a black color include bisbenzofuranone-based pigments, azomethine-based pigments, perylene-based pigments and azo-based dyes.

The colorant that exhibits a green color may be a green pigment, a green dye or an intermediate thereof. Examples of the green colorant include C.I. Pigment Green 7, 36, 37, 58, and the like. Examples of the green dye include C.I. Acid Green 25, 41, and the like. These colorants may be used singly, or two or more colorants may be mixed.

The colorant that exhibits a blue color may be a blue pigment or a blue dye. Examples of the blue pigment include C.I. Pigment Blue 15, 15:3, 15:4, 15:6, 6, 22, 60, and the like. Examples of the blue dye include C.I. Acid Blue 41, 83, 90, 113, 129, and the like. These colorants may be used singly, or two or more colorants may be mixed.

The colorant that exhibits a red color may be a red pigment or a red dye. Examples of the red pigment include C.I. Pigment Red 123, 155, 168, 177, 180, 217, 220, 254, and the like. Examples of the red dye include C.I. Acid Red 37, 50, 111, 114, 257, 266, and the like. These colorants may be used singly, or two or more colorants may be mixed.

The colorant that exhibits a yellow color may be a yellow pigment or a yellow dye. Examples of the yellow pigment include C.I. Pigment Yellow 138, 139, 150, 185, and the like. Examples of the yellow dye include C.I. Acid Yellow 17, 49, 67, 72, 127, 110, and the like. These colorants may be used singly, or two or more colorants may be mixed.

The colorant that exhibits a violet color may be a violet pigment. Examples of the violet pigment include C.I. Pigment Violet 1, 19, 23, 27, 29, 30, 32, 37, 40, 42, 50, and the like. These colorants may be used singly, or two or more colorants may be mixed.

The colorant that exhibits a magenta color may be a magenta pigment. Examples of the magenta pigment include C.I. Pigment Red 7, 14, 41, 48:1, 48:2, 48:3, 48:4, 81:1, 81:2, 81:3, 146, 177, 178, 184, 185, 187, 200, 202, 208, 210, 246, 254, 255, 264, 270, 272, and the like. These colorants may be used singly, or two or more colorants may be mixed.

The colorant that exhibits a cyan color may be a cyan pigment. Examples of the cyan pigment include C.I. Pigment Blue 15:1, 15:2, 15:3, 15:4, 15:6, 16, 80, and the like.

The colorant that exhibits an orange color may be an orange pigment. Examples of the orange pigment include C.I. Pigment Orange 36, 43, 51, 55, 59, 61, 71, 73, and the like.

Examples of the infrared absorbing dye include anthraquinone-based dyes, cyanine-based dyes, phthalocyanine-based dyes, dithiol-based dyes, diimmonium-based dyes, squarylium-based dyes and croconium-based dyes.

As described above, the polymerizable compound contains a first bi- or higher functional (meth)acrylate containing an amino group.

When a coloring composition containing a photopolymerization initiator and a polymerizable compound is patterned by photolithography, polymerization reaction of the polymerizable compound is inhibited by oxygen present in the atmosphere and in the exposure apparatus. The inhibition of polymerization reaction by oxygen is likely to occur near the surface of the coating film where a relatively large amount of oxygen is present, resulting in poor curing of the coating film containing the coloring composition and a decrease in rectangularity of the cross-section of the infrared pass filter 12P.

Such problems are not solved only by increasing the amount of photopolymerization initiator added to the photosensitive coloring composition. Further, when the amount of photopolymerization initiator added is increased, the sensitivity of the photosensitive coloring composition to exposure becomes excessively high, making it difficult to control the line width of the infrared pass filter 12P. In addition, adjusting the ratio of the photopolymerization initiator to the polymerization inhibitor is effective for increasing the controllability in the line width of the infrared pass filter 12P, but it is not possible to achieve both rectangularity of the cross-section of the infrared pass filter 12P and controllability in the line width.

Compounds containing an amino group have the effect of scavenging oxygen that inhibits polymerization reaction. Therefore, when the photosensitive coloring composition contains the first (meth)acrylate, inhibition of polymerization reaction can be suppressed. Further, when the polymerizable compound contains bi- or higher functional (meth)acrylate containing an amino group, polymerization reaction can be accelerated compared with the case where the (meth)acrylate is monofunctional. Accordingly, curing of the coating film containing the photosensitive coloring composition proceeds, resulting in an increase in rectangularity of the cross-section of the infrared pass filter 12P.

The first (meth)acrylate preferably has a weight average molecular weight of 150 or greater and 5,000 or less. The weight average molecular weight of 150 or greater can suppress insufficient curing of the exposed region during patterning of the coating film by photolithography, preventing a decrease in accuracy of the shape of the infrared pass filter 12P. The weight average molecular weight of 5,000 or less can suppress a decrease in solubility in the developer, preventing a decrease in accuracy of the shape of the infrared pass filter 12P.

When the total mass of the solid content of the photosensitive coloring composition is set to 100 mass %, the content of the first (meth)acrylate is preferably 0.1 mass % or greater and 20 mass % or less. The content of first (meth)acrylate is more preferably 0.3 mass % or greater and 15 mass % or less, and still more preferably 0.5 mass % or greater and 10 mass % or less. That is, the percentage of the first (meth)acrylate relative to the solid content mass of the photosensitive coloring composition is preferably 0.1% or greater and 20% or less, more preferably 0.3% or greater and 15% or less, and still more preferably 0.5% or greater and 10% or less.

The content of the first (meth)acrylate of 0.1 mass % or greater can accelerate polymerization reaction, increasing the rectangularity of the cross-section of the infrared pass filter 12P. The content of the first (meth)acrylate of 20 mass % or less can suppress a decrease in density of the colorant in the photosensitive coloring composition, preventing deterioration of the spectral properties of the infrared pass filter 12P.

Examples of the bi- or higher functional (meth)acrylate containing an amino group include EBECRYL 80 (manufactured by Daicel-Allnex Ltd., EBECRYL is a registered trademark), EBECRYL 7100 (manufactured by Daicel-Allnex Ltd.), CN 371 NS (manufactured by Arkema Inc.), CN 550 (manufactured by Arkema Inc.), CN 551 (manufactured by Arkema Inc.), Laromer 83F (manufactured by BASF Corp., Laromer is a registered trademark) and Laromer 84F (manufactured by BASF Corp.). These (meth)acrylates may be used singly, or two or more (meth)acrylates may be mixed.

The polymerization inhibitor is preferably methylhydroquinone. Examples of the polymerization inhibitor include quinone-based inhibitors, hindered phenol-based inhibitors, nitrosoamine-based inhibitors and phenothiazine-based inhibitors. These polymerization inhibitors may be used singly or may be used as a mixture containing two or more.

The photopolymerization initiator is preferably an oxime ester-based photopolymerization initiator or an α-aminoalkylphenone-based photopolymerization initiator, and more preferably an oxime ester-based photopolymerization initiator. The oxime ester-based photopolymerization initiator has high sensitivity to exposure light, and thus it is possible to reduce the content of the photopolymerization initiator in the photosensitive coloring composition. The oxime ester-based photopolymerization initiator may be 1,2-octanedione, 1-[4-(phenylthio)phenyl-2-(O-benzoyloxime)], ethanone, 1-[9-ethyl-6-(2-methylbenzoyl)-9H-carbazol-3-yl]-, 1-(O-acetyloxime), or the like.

The α-aminoalkylphenone-based photopolymerization initiator may be 2-benzyl-2-dimethylamino-1-(4-morpholinophenyl)-butanone-1, 2-dimethylamino-2-(4-methyl-benzyl)-1-(4-morpholin-4-yl-phenyl)-butan-1-one, or the like.

In addition to the oxime ester-based photopolymerization initiator and the α-aminoalkylphenone-based photopolymerization initiator, the photopolymerization initiator may contain other photopolymerization initiators than these. Examples of such other photopolymerization initiators include acetophenone-based photopolymerization initiators, benzoin-based photopolymerization initiators, benzophenone-based photopolymerization initiators, thioxanthone-based photopolymerization initiators, triazine-based photopolymerization initiators, borate-based photopolymerization initiators, carbazole-based photopolymerization initiators and imidazole-based photopolymerization initiators.

Examples of the acetophenone-based photopolymerization initiator include 4-phenoxydichloroacetophenone, 4-t-butyl-dichloroacetophenone, diethoxyacetophenone, 1-(4-isopropylphenyl)-2-hydroxy-2-methylpropane-1-one, 1-hydroxycyclohexyl phenyl ketone, and 2-methyl-1-[4-(methylthio)phenyl]-2-morpholinopropane-1-one.

Examples of the benzoin-based photopolymerization initiator include benzoin, benzoin methyl ether, benzoin ethyl ether, benzoin isopropyl ether and benzyl dimethyl ketal. Examples of the benzophenone-based photopolymerization initiator include benzophenone, benzoyl benzoate, methyl benzoyl benzoate, 4-phenylbenzophenone, hydroxybenzophenone, acrylated benzophenone and 4-benzoyl-4′-methyldiphenyl sulfide. Examples of the thioxanthone-based photopolymerization initiators include thioxanthone, 2-chlorothioxanthone, 2-methylthioxanthone, isopropylthioxanthone and 2, 4-diisopropylthioxanthone.

Examples of the triazine-based photopolymerization initiator include 2,4,6-trichloro-s-triazine, 2-phenyl 4,6-bis(trichloromethyl)-s-triazine, 2-(p-methoxyphenyl-4,6-bis(trichloromethyl)-s-triazine, 2-(p-tolyl)-4,6-bis(trichloromethyl)-s-triazine, 2-piperonyl-4,6-bis(trichloromethyl)-s-triazine, 2,4-bis(trichloromethyl)-6-styryl-chloromethyl)-s-triazine, 2,4-bis(trichloromethyl)-6-styryl-s-triazine, 2-(naphth-1-yl)-4,6-bis(trichloromethyl)-s-triazine, 2-(4-methoxy-naphth-1-yl)-4,6-bis(trichloromethyl)-s-triazine, 2,4-trichloromethyl(piperonyl)-6-triazine and 2,4-trichloromethyl(4′-methoxystyryl)-6-triazine.

These photopolymerization initiators may be used singly, or two or more photopolymerization initiators may be mixed.

In an embodiment of the present invention, a percentage ((M_{M1}/M_{P1})×100) of the mass of the first (meth)acrylate (M_{M1}) relative to the mass of the photopolymerization initiator (M_{P1}) is 50 or greater and 500 or less. The percentage of the mass of the first (meth)acrylate relative to the mass of the photopolymerization initiator is preferably 100 or greater and 400 or less.

The percentage of the mass of the first (meth)acrylate relative to the mass of the photopolymerization initiator of 50% or greater can suppress insufficient curing of the pattern formed of the photosensitive coloring composition, preventing a decrease in rectangularity of the cross-sectional shape of the pattern. The percentage of the mass of the first (meth)acrylate relative to the mass of the photopolymerization initiator of 500% or less can prevent the sensitivity from becoming excessively high, whereby the difficulty in controlling the line width of the infrared pass filter can be reduced.

The percentage ((M_{P2}/M_{P1})×100) of the mass (M_{P2}) of the polymerization inhibitor relative to the mass (M_{P1}) of the photopolymerization initiator is 3% or greater and 30% or less, and preferably 4% or greater and 15% or less. The percentage of the mass of the polymerization inhibitor relative to the mass of the photopolymerization initiator of 3% or greater can prevent the sensitivity of the photosensitive coloring composition from becoming excessively high, whereby the difficulty in controlling the line width of the infrared pass filter 12P can be reduced. The percentage of the mass of the polymerization inhibitor relative to the mass of the photopolymerization initiator of 30 mass % or less can suppress insufficient curing of the infrared pass filter 12P, preventing a decrease in rectangularity of the cross-sectional shape of the infrared pass filter 12P.

Thus, when satisfying the following conditions, the photosensitive coloring composition for an infrared pass filter can achieve both rectangularity in the cross-section of the infrared pass filter and controllability in the line width of the infrared pass filter.
Condition 1 The percentage of the mass of the polymerization inhibitor relative to the mass of the photopolymerization initiator is 3% or greater and 30% or less.
Condition 2 The percentage of the mass of the first (meth)acrylate relative to the mass of the photopolymerization initiator is 50% or greater and 500% or less.

A ratio (M_{P1}/M_{PC}) of a mass (M_{P1}) of the photopolymerization initiator to a mass (M_{PC}) of the polymerizable compound is preferably 0.01 or greater and 0.5 or less, and more preferably 0.05 or greater and 0.4 or less. The ratio of the mass of the photopolymerization initiator to the mass of the polymerizable compound of 0.01 or greater can suppress insufficient curing of the exposed region, preventing a decrease in accuracy of the shape of the infrared pass filter 12P. The ratio of the mass of the photopolymerization initiator to the mass of the polymerizable compound of 0.5 or less can prevent the sensitivity of the photosensitive coloring composition from becoming excessively high, preventing a decrease in accuracy of the shape of the infrared pass filter 12P.

The polymerizable compound may further contain a second tri- or higher functional (meth)acrylate containing no amino groups. That is, the polymerizable compound may further contain a second (meth)acrylate having three or more functional groups. None of the three or more functional groups in the second (meth)acrylate are amino groups. Due to the second (meth)acrylate being contained in the polymerizable compound, the sensitivity of the photosensitive coloring composition during exposure can be increased. The tri- or higher functional (meth)acrylate containing no amino groups is preferably a trifunctional (meth)acrylate containing no amino groups. Due to the trifunctional (meth)acrylate being contained in the polymerizable compound, the sensitivity can be prevented from becoming excessively high.

When the total mass of the polymerizable compound is set to 100 mass %, the content of the second (meth)acrylate is preferably 20 mass % or greater and 95 mass % or less. That is, the percentage of the second (meth)acrylate relative to the total mass of the polymerizable compound is preferably 20% or greater and 95% or less. Due to the first (meth)acrylate and the second (meth)acrylate being contained in the photosensitive coloring composition at the above-mentioned ratios, it is possible to increase the accuracy in the shape of the infrared pass filter 12P.

Examples of the polymerizable compound include pentaerythritol triacrylate, pentaerythritol tetraacrylate, trimethylolpropane triacrylate, trimethylolpropane PO-modified (n=1) triacrylate, trimethylolpropane PO-modified (n=2) triacrylate, trimethylolpropane EO-modified (n=1) triacrylate, trimethylolpropane EO-modified (n=2) triacrylate, dipentaerythritol pentaacrylate, dipentaerythritol hexaacrylate, pentaerythritol tetraacrylate, ditrimethylol tetraacrylate, EO-modified isocyanurate diacrylate and EO-modified isocyanurate triacrylate. These polymerizable compounds may be used singly, or two or more polymerizable compounds may be mixed.

The binder resin is obtained by copolymerizing at least one of monomers and oligomers. Monomers and oligomers are raw materials of the binder resin, and the binder resin may be formed using two or more raw materials. Examples of the monomers for producing a binder resin and monomers constituting oligomers for producing a binder resin include (meth)acrylic acid ester, (meth)acrylic acid, styrene, vinyl acetate, hydroxyethyl vinyl ether, ethylene glycol divinyl ether, pentaerythritol trivinyl ether, (meth)acrylamide, N-hydroxymethyl (meth)acrylamide, N-vinylformamide and acrylonitrile.

Examples of the (meth)acrylic acid ester include methyl acrylate (meth)acrylate, ethyl (meth)acrylate, 2-hydroxyethyl (meth)acrylate, 2-hydroxypropyl (meth)acrylate, cyclohexyl (meth)acrylate, ß-carboxyethyl (meth)acrylate, diethylene glycol di(meth)acrylate, 1,6-hexanediol di(meth)acrylate, triethylene glycol di(meth)acrylate, tripropylene glycol di(meth)acrylate, trimethylolpropane tri(meth)acrylate, pentaerythritol tri(meth)acrylate, glycidyl (meth)acrylate, 1,6-hexanediol diglycidyl ether di(meth)acrylate, bisphenol A diglycidyl ether di(meth)acrylate, neopentyl glycol diglycidyl ether di(meth)acrylate, dipentaerythritol hexa(meth)acrylate, tricyclodecanyl (meth)acrylate, ester acrylate, (meth)acrylic acid ester of methylated melamine, epoxy (meth)acrylate and urethane acrylate.

The binder resin is preferably produced by copolymerizing monomers having acidic groups. Accordingly, the binder resin can be dissolved in an alkaline developer. The acidic group may be a carboxyl group. The carboxyl group-containing monomer may contain at least one carboxyl group. The carboxyl group-containing monomer may be an unsaturated monocarboxylic acid or an unsaturated polyvalent carboxylic acid. Examples of the unsaturated polyvalent carboxylic acid include an unsaturated dicarboxylic acid and an unsaturated tricarboxylic acid.

Examples of the unsaturated monocarboxylic acid include acrylic acid, methacrylic acid, crotonic acid, α-chloroacrylic acid and cinnamic acid. Examples of the unsaturated dicarboxylic acid include maleic acid, fumaric acid, itaconic acid, citraconic acid and mesaconic acid. The unsaturated polyvalent carboxylic acid may be an acid anhydride thereof. Examples of the acid anhydride of the unsaturated polyvalent carboxylic acid include maleic anhydride, itaconic anhydride and citraconic anhydride. The unsaturated polyvalent carboxylic acid may be a mono(2-methacryloyloxyalkyl) ester thereof. Examples of the mono(2-methacryloyloxyalkyl) ester of the unsaturated polyvalent carboxylic acid include mono(2-acryloyloxyethyl) succinate, mono(2-methacryloyloxyethyl) succinate, mono(2-acryloyloxyethyl) phthalate and mono(2-methacryloyloxyethyl) phthalate. The unsaturated polyvalent carboxylic acid may be a mono(meth)acrylate of a dicarboxy polymer located at both ends thereof. Examples of the mono(meth)acrylate of the dicarboxy polymer of the unsaturated polyvalent carboxylic acid include @-carboxy polycaprolactone monoacrylate and @-carboxy polycaprolactone monomethacrylate. These carboxyl group-containing monomers may be used singly, or two or more carboxyl group-containing monomers may be mixed.

The binder resin preferably has a weight average molecular weight of 5,000 or greater and 20,000 or less. The weight average molecular weight of 5,000 or greater can cause the photosensitive coloring composition to contain compounds having a molecular weight large enough to sufficiently cure the exposed region during patterning of the coating film by photolithography, improving the accuracy in the shape of the pattern. The weight average molecular weight of 20,000 or less can prevent a decrease in developability of the developer used in photolithography, preventing a decrease in accuracy of the shape of the pattern.

The binder resin may be a thermosetting resin. Examples of the thermosetting resin include epoxy resins, benzoguanamine resins, rosin-modified maleic acid resins, rosin-modified fumaric acid resins, melamine resins, urea resins and phenol resins. These thermosetting resins may be used singly, or two or more thermosetting resins may be mixed.

The photosensitive coloring composition further contains a solvent for dissolving or dispersing the above-mentioned materials. Examples of the solvent includes cyclohexane, cyclohexanone, ethyl cellosolve acetate, tetrahydrofuran, butyl cellosolve acetate, 1-methoxy-2-propyl acetate, diethylene glycol dimethyl ether, propylene glycol monomethyl ether acetate, ethylbenzene, ethylene glycol diethyl ether, xylene, ethyl cellosolve, methyl-n amyl ketone, propylene glycol monomethyl ether toluene, methyl ethyl ketone, ethyl acetate, methanol, ethanol, isopropyl alcohol, butanol, isobutyl ketone and petroleum solvents. Those solvents may be used singly, or two or more solvents may be mixed.

The coloring composition may contain additives other than the above-mentioned materials. The additives may be, for example, at least one of surfactants and storage stabilizers. That is, the coloring composition may contain only one of the surfactant and storage stabilizer as an additive or may contain both the surfactant and storage stabilizer as additives.

The surfactant may be an anionic surfactant, a nonionic surfactant, a cationic surfactant, an amphoteric surfactant or a silicone surfactant. Examples of the anionic surfactant include sodium lauryl sulfate, polyoxyethylene alkyl ether sulfate, sodium dodecylbenzene sulfonate, alkali salts of styrene-acrylic acid copolymers, sodium stearate, sodium alkylnaphthalene sulfonate, sodium alkyl diphenyl ether disulfonate, monoethanolamine lauryl sulfate, triethanolamine lauryl sulfate, ammonium lauryl sulfate, monoethanolamine stearate, sodium stearate, sodium lauryl sulfate, monoethanolamine of styrene-acrylic acid copolymers and polyoxyethylene alkyl ether phosphate esters.

Examples of the nonionic surfactant include polyoxyethylene oleyl ether, polyoxyethylene lauryl ether, polyoxyethylene nonylphenyl ether, polyoxyethylene alkyl ether phosphate ester, polyoxyethylene sorbitan monostearate and polyethylene glycol monolaurate. Examples of the cationic surfactant include alkyl quaternary ammonium salts and ethylene oxide adducts thereof. Examples of the amphoteric surfactant include alkyl betaines such as alkyldimethylaminoacetic acid betaines and alkyl imidazolines. These surfactants may be used singly, or two or more surfactants may be mixed.

Examples of the storage stabilizer include quaternary ammonium chlorides, organic acids, methyl ethers of organic acids, t-butyl pyrocatechol, organic phosphines and phosphites. Examples of the quaternary ammonium chlorides include benzyltrimethyl chlorides and diethylhydroxyamines. Examples of the organic acids include lactic acids and oxalic acids. Examples of the organic phosphines include triethylphosphines and triphenylphosphines. These storage stabilizers may be used singly, or two or more storage stabilizers may be mixed.

### Method of Producing Photosensitive Coloring Composition

A method of producing a photosensitive coloring composition is a method of producing a photosensitive coloring composition containing a colorant, a polymerizable compound, a photopolymerization initiator and a polymerization inhibitor. The production method includes mixing the colorant, the polymerizable compound, the photopolymerization initiator and the polymerization inhibitor.

In a production method according to an embodiment of the present invention, a colorant used is such that the infrared pass filter has transmission properties in which the average transmittance in the wavelength band of 400 nm or more and 800 nm or less is 30% or less and the average transmittance in the wavelength band of 900 nm or more and 1,100 nm or less is 75% or greater. Further, in this production method, the photopolymerization initiator and the polymerizable compound are mixed such that the percentage of the mass of the first (meth)acrylate relative to the mass of the photopolymerization initiator is 50% or greater and 500% or less. Further, in this production method, the photopolymerization initiator and the polymerization inhibitor are mixed such that the percentage of the mass of the polymerization inhibitor relative to the mass of the photopolymerization initiator is 3% or greater and 30% or less.

In one example, in preparation of a photosensitive coloring composition, the colorant is first dispersed in a solvent to produce a colorant dispersion. Then, the polymerizable compound, the binder resin, the photopolymerization initiator, the polymerization inhibitor and the solvent are added and mixed with the colorant dispersion to prepare a mixed solution. After the mixed solution is stirred for a predetermined period of time, the mixed solution is filtered to obtain a photosensitive coloring composition.

### EXAMPLES

### Preparation of Colorant Dispersion

A colorant, a dispersant and a solvent were mixed at a ratio described below to prepare a mixed solution.

Colorant: manufactured by BASF Corp., Lumogen Black K0088: 12.0 parts (Lumogen is a registered trademark)

Dispersant: manufactured by BYK-Chemie Japan Co., Ltd., Disperbyk-2001 (solid content 46%): 17.4 parts (Disperbyk is a registered trademark) Solvent: propylene glycol monomethyl ether acetate: 70.6 parts

Then, the mixed solution was subjected to dispersion treatment for 1.5 hours with a dissolver (manufactured by Eko Instruments Co., Ltd., DISPERMAT LC55) using zirconia beads with a diameter of 0.1 mm. Subsequently, the mixed solution was filtered using a 5-μm filter to thereby obtain a colorant dispersion.

### Synthesis of Binder Resin

60 parts by weight of propylene glycol monomethyl ether acetate, 32 parts by weight of methacrylic acid benzyl, 8 parts by weight of methacrylic acid, and 0.60 parts by weight of benzoyl peroxide were prepared. These were placed in a reaction vessel having a stirring device and a reflux tube, and then stirred and refluxed for 8 hours while being heated to 80° C. with nitrogen gas being introduced into the reaction vessel. Thus a binder resin was obtained.

### Preparation of Photosensitive Coloring Composition

The colorant dispersion, the polymerizable compound, the binder resin, the photopolymerization initiator, the polymerization inhibitor and the solvent were mixed at ratios shown in Tables 1 to 3 below to obtain mixed solutions. After the mixed solutions were stirred for 1 hour, the mixed solutions were filtered using a 0.45-μm filter to obtain photosensitive coloring compositions.

Polymerizable compounds 1 to 4, photopolymerization initiator, polymerization inhibitor and solvent shown in Tables 1 to 3 below are as follows. Among the polymerizable compounds, polymerizable compounds 1 to 3 are examples of the first (meth)acrylate, and polymerizable compound 4 is an example of the second (meth)acrylate.

Polymerizable compound 1: manufactured by Daicel-Allnex Ltd., EBECRYL 80 (tetrafunctional, weight average molecular weight 1,000)

Polymerizable compound 2: manufactured by Daicel-Allnex Ltd., EBECRYL 7100 (bifunctional, weight average molecular weight 400)

Polymerizable compound 3: manufactured by Arkema Inc., CN371 NS (bifunctional, weight average molecular weight 1,600)

Polymerizable compound 4: manufactured by Toagosei Co., Ltd., M350 (trifunctional, weight average molecular weight 428.5)

Photopolymerization initiator: manufactured by BASF Corp., OXE-02

Polymerization inhibitor: manufactured by Tokyo Chemical Industry Co., Ltd., methylhydroquinone

Solvent: propylene glycol monomethyl ether acetate

Further, first to third ratios are as follows.

First ratio: percentage of the mass of the polymerization inhibitor relative to the mass of the photopolymerization initiator

Second ratio: percentage of the mass of the first (meth)acrylate relative to the mass of the photopolymerization initiator

Third ratio: content of the first (meth)acrylate relative to the total solid content mass of the photosensitive coloring composition

TABLE 1
Composition 2 Composition 3

| | Composition 1 | Composition 2 | Composition 3 | Composition 4 | Composition 5 |
|---|---|---|---|---|---|
| Colorant dispersion | 71.250 | 71.250 | 71.250 | 71.250 | 71.250 |
| Polymerizable | 0.720 | — | — | 0.360 | — |
| compound 1 | | | | | |
| Polymerizable | — | 0.720 | — | 0.360 | 0.360 |
| compound 2 | | | | | |
| Polymerizable | — | — | 0.720 | — | 0.360 |
| compound 3 | | | | | |
| Polymerizable | 1.530 | 1.530 | 1.530 | 1.530 | 1.530 |
| compound 4 | | | | | |
| Binder resin | 1.142 | 1.142 | 1.142 | 1.142 | 1.142 |
| Photopolymerization | 0.340 | 0.340 | 0.340 | 0.340 | 0.340 |
| initiator | | | | | |
| Polymerization | 0.018 | 0.018 | 0.018 | 0.018 | 0.018 |
| inhibitor | | | | | |
| Solvent | 25.000 | 25.000 | 25.000 | 25.000 | 25.000 |
| Total | 100.000 | 100.000 | 100.000 | 100.000 | 100.000 |
| First ratio (%) | 5.30 | 5.30 | 5.30 | 5.30 | 5.30 |
| Second ratio (%) | 212.01 | 212.01 | 212.01 | 212.01 | 212.01 |
| Third ratio (mass %) | 4.00 | 4.00 | 4.00 | 4.00 | 4.00 |

TABLE 2

| | Composition 6 | Composition 7 | Composition 8 | Composition 9 | Composition 10 |
|---|---|---|---|---|---|
| Colorant dispersion | 71.250 | 71.250 | 71.250 | 71.250 | 74.986 |
| Polymerizable | 0.360 | 1.200 | 1.400 | 0.500 | — |
| compound 1 | | | | | |
| Polymerizable | — | — | — | — | — |
| compound 2 | | | | | |
| Polymerizable | 0.360 | — | — | — | — |
| compound 3 | | | | | |
| Polymerizable | 1.530 | 1.530 | 1.530 | 1.530 | 1.523 |
| compound 4 | | | | | |
| Binder resin | 1.142 | 1.142 | 1.142 | 1.142 | 1.137 |
| Photopolymerization | 0.340 | 0.340 | 0.340 | 0.380 | 0.339 |
| initiator | | | | | |
| Polymerization | 0.018 | 0.049 | 0.099 | 0.013 | 0.015 |
| inhibitor | | | | | |
| Solvent | 25.000 | 24.489 | 24.239 | 25.185 | 22.000 |
| Total | 100.000 | 100.000 | 100.000 | 100.000 | 100.000 |
| First ratio (%) | 5.30 | 14.43 | 29.15 | 3.42 | 4.42 |
| Second ratio (%) | 212.01 | 353.34 | 412.23 | 131.58 | 0.00 |
| Third ratio (mass %) | 4.00 | 6.48 | 7.46 | 2.81 | 0.00 |

TABLE 3

| | Composition 11 | Composition 12 | Composition 13 | Composition 14 | Composition 15 |
|---|---|---|---|---|---|
| Colorant dispersion | 74.985 | 71.250 | 71.250 | 71.250 | 71.250 |
| Polymerizable | 0.010 | 0.720 | 0.720 | 0.720 | 0.720 |
| compound 1 | | | | | |
| Polymerizable | — | — | — | — | — |
| compound 2 | | | | | |
| Polymerizable | — | — | — | — | — |
| compound 3 | | | | | |
| Polymerizable | 1.516 | 1.530 | 1.530 | 1.530 | 1.530 |
| compound 4 | | | | | |
| Binder resin | 1.135 | 1.142 | 1.142 | 1.142 | 1.142 |
| Photopolymerization | 0.339 | 0.340 | 0.340 | 0.340 | 0.340 |
| initiator | | | | | |
| Polymerization | 0.015 | — | 0.004 | 0.007 | 0.140 |
| inhibitor | | | | | |
| Solvent | 22.000 | 25.020 | 25.010 | 25.010 | 24.878 |
| Total | 100.000 | 100.000 | 100.000 | 100.000 | 100.000 |
| First ratio (%) | 4.42 | 0.00 | 1.18 | 2.06 | 41.22 |
| Second ratio (%) | 2.95 | 212.01 | 212.01 | 212.01 | 212.01 |
| Third ratio (mass %) | 0.06 | 4.00 | 4.00 | 4.00 | 3.97 |

### Evaluation of Spectral Properties

### Preparation of Test Substrate

Each photosensitive coloring composition was applied onto a glass substrate using a spin coater so that the thickness after baking treatment became the thickness shown in Table 4 to thereby form a coating film. Then, the coating film on the glass substrate was subjected to baking treatment for 2 minutes using a hot plate set at 100° ° C. When the infrared pass filter was composed of multiple layers, each layer was formed by the method described above. Thus, test substrates of Test examples 1-1 to 1-16 were obtained.

TABLE 4

| | 1st layer | | 2nd layer | | 3rd layer | |
|---|---|---|---|---|---|---|
| | | Thickness | | Thickness | | Thickness |
| | Composition | (μm) | Composition | (μm) | Composition | (μm) |
| Test ex. 1-1 | Composition 1 | 1.4 | — | — | — | — |
| Test ex. 1-2 | Composition 2 | 1.4 | — | — | — | — |
| Test ex. 1-3 | Composition 3 | 1.4 | — | — | — | — |
| Test ex. 1-4 | Composition 4 | 1.4 | — | — | — | — |
| Test ex. 1-5 | Composition 5 | 1.4 | — | — | — | — |
| Test ex. 1-6 | Composition 6 | 1.4 | — | — | — | — |
| Test ex. 1-7 | Composition 7 | 1.4 | — | — | — | — |
| Test ex. 1-8 | Composition 8 | 1.4 | — | — | — | — |
| Test ex. 1-9 | Composition 9 | 1.4 | — | — | — | — |
| Test ex. 1-10 | Composition 1 | 0.5 | Composition 1 | 0.5 | Composition 1 | 0.5 |
| Test ex. 1-11 | Composition 10 | 1.4 | — | — | — | — |
| Test ex. 1-12 | Composition 11 | 1.4 | — | — | — | — |
| Test ex. 1-13 | Composition 12 | 1.4 | — | — | — | — |
| Test ex. 1-14 | Composition 13 | 1.4 | — | — | — | — |
| Test ex. 1-15 | Composition 14 | 1.4 | — | — | — | — |
| Test ex. 1-16 | Composition 15 | 1.4 | — | — | — | — |

### Evaluation Method

For the infrared pass filters included in the test substrates of the respective test examples, the transmittance in the wavelength band of 400 nm or more and 1,100 nm or less was measured using a spectrophotometer (manufactured by Hitachi High-Technologies Corporation, U-4100). Table 5 shows the measurement results of transmittance. In Table 5, the first transmittance is the average transmittance in the wavelength band of 400 nm or more and 800 nm or less, and the second transmittance is the average transmittance in the wavelength band of 900 nm or more and 1,100 nm or less.

### Evaluation Results

Table 5 below shows the measurement results of the first transmittance and the second transmittance of the infrared pass filters included in the test substrates of Test examples 1-1 to 1-16.

TABLE 5

| | 1st transmittance | 2nd transmittance |
|---|---|---|
| Test ex. 1-1 | 8.32 | 88.10 |
| Test ex. 1-2 | 8.12 | 87.93 |
| Test ex. 1-3 | 8.78 | 88.73 |
| Test ex. 1-4 | 8.56 | 88.05 |
| Test ex. 1-5 | 8.87 | 87.52 |
| Test ex. 1-6 | 8.49 | 87.88 |
| Test ex. 1-7 | 8.74 | 88.49 |
| Test ex. 1-8 | 8.92 | 88.63 |
| Test ex. 1-9 | 7.89 | 88.73 |
| Test ex. 1-10 | 6.65 | 87.12 |
| Test ex. 1-11 | 8.42 | 87.86 |
| Test ex. 1-12 | 8.57 | 87.79 |
| Test ex. 1-13 | 8.39 | 88.45 |
| Test ex. 1-14 | 8.45 | 88.82 |
| Test ex. 1-15 | 8.33 | 88.49 |
| Test ex. 1-16 | 8.37 | 88.76 |

As shown in Table 5, the test substrates in Test examples 1-1 to 1-16 were found to have the first transmittance of 30% or less and the second transmittance of 75% or greater. Specifically, the test substrates in Test examples 1-1 to 1-16 were found to have the first transmittance of less than 9% and the second transmittance of 87% or greater.

### Evaluation of Shape

### Preparation of Test Substrate

First, a silicon wafer having a planarization layer was prepared. Then, each photosensitive coloring composition was applied onto the planarization layer using a spin coater so that the thickness after baking treatment became the thickness shown in Table 6 to thereby form a coating film. Then, the coating film on the planarization layer was subjected to baking treatment for 2 minutes using a hot plate set at 100° C. Subsequently, the coating film was exposed to light using a photomask for forming square pixels. In exposure, the coating film was irradiated with ultraviolet light having a wavelength of 365 nm.

The photomask used was formed to form four types of infrared pass filters having different side lengths, that is, different pixel sizes. Specifically, the photomask was formed to form an infrared pass filter having a pixel size of 2.0 μm, an infrared pass filter having a pixel size of 1.8 μm, an infrared pass filter having a pixel size of 1.6 μm and an infrared pass filter having a pixel size of 1.4 μm in a single exposure.

Exposure of the coating film was performed using an exposure machine (manufactured by Canon Inc., FPA-5510iZ). In exposure of the coating film, the exposure amount was increased in steps of 500 J/m² in the range of 100 J/m² or more and 10,000 J/m² or less, and the exposed region of the coating film was changed for each exposure amount. Subsequently, the exposed coating film was developed using a 0.2% tetraammonium hydroxide aqueous solution. Then, washing and drying were performed in sequence. Thus, an infrared pass filter having a predetermined pixel size was formed.

When the infrared pass filter was composed of multiple layers, a first layer of the infrared pass filter was formed by the method described above. Subsequently, coating film formation, exposure and development were performed layer by layer to obtain an infrared pass filter composed of multiple layers.

Thus, test substrates of Test examples 2-1 to 2-16 were obtained.

TABLE 6

| | 1st layer | | 2nd layer | | 3rd layer | |
|---|---|---|---|---|---|---|
| | | Thickness | | Thickness | | Thickness |
| | Composition | (μm) | Composition | (μm) | Composition | (μm) |
| Test ex. 2-1 | Composition 1 | 1.4 | — | — | — | — |
| Test ex. 2-2 | Composition 2 | 1.4 | — | — | — | — |
| Test ex. 2-3 | Composition 3 | 1.4 | — | — | — | — |
| Test ex. 2-4 | Composition 4 | 1.4 | — | — | — | — |
| Test ex. 2-5 | Composition 5 | 1.4 | — | — | — | — |
| Test ex. 2-6 | Composition 6 | 1.4 | — | — | — | — |
| Test ex. 2-7 | Composition 7 | 1.4 | — | — | — | — |
| Test ex. 2-8 | Composition 8 | 1.4 | — | — | — | — |
| Test ex. 2-9 | Composition 9 | 1.4 | — | — | — | — |
| Test ex. 2-10 | Composition 1 | 0.5 | Composition 1 | 0.5 | Composition 1 | 0.5 |
| Test ex. 2-11 | Composition 10 | 1.4 | — | — | — | — |
| Test ex. 2-12 | Composition 11 | 1.4 | — | — | — | — |
| Test ex. 2-13 | Composition 12 | 1.4 | — | — | — | — |
| Test ex. 2-14 | Composition 13 | 1.4 | — | — | — | — |
| Test ex. 2-15 | Composition 14 | 1.4 | — | — | — | — |
| Test ex. 2-16 | Composition 15 | 1.4 | — | — | — | — |

### Evaluation of Controllability in Line Width

### Evaluation Method

The line width of the infrared pass filter when viewed in a direction perpendicular to the surface of the silicon wafer was measured using a scanning electron microscope (manufactured by Hitachi High-Tech Corporation, S-7840). Specifically, the line width of the infrared pass filter for each pixel size was measured in each of the exposed regions irradiated with different exposure amounts. The line width was measured for each pixel size in 20 infrared pass filters, and the average value of the 20 infrared pass filters was calculated.

For the line width of the infrared pass filter, each pixel size −0.5 μm to +0.05 μm was taken as the appropriate line width. In each of the exposed regions, whether the average value of the line widths of the infrared pass filters for each pixel size was within the range of the average line width was determined. Then, the controllability in the line width of the infrared pass filter was evaluated according to the following evaluation criteria.

Good: Appropriate line width at the exposure amount of 1,000 J/m² or more

Fair: Appropriate line width at the exposure amount of 500 J/m² or more and less than 1,000 J/m²

Poor: Appropriate line width at the exposure amount of less than 500 J/m²

For the infrared pass filter having the pixel size of 1.4 μm in the test substrate of each test example, an exposure amount at which the difference value between the line width of the infrared pass filter and the pixel size was smallest was identified as a first exposure amount. Then, in the first exposure amount, a first difference value, which was the absolute value of the difference value between the line width and the pixel size, was calculated for the 20 infrared pass filters, and a first average value of the first difference values in the 20 infrared pass filters was calculated.

On the other hand, an exposure amount larger than the first exposure amount by 500 J/m² was identified as a second exposure amount. Then, in the second exposure amount, a second difference value, which was the absolute value of the difference value between the line width and the pixel size, was calculated for the 20 infrared pass filters having the pixel size of 1.4 μm, and a second average value of the second difference values in the 20 infrared pass filters was calculated. Further, the absolute value of the difference value obtained by subtracting the second average value from the first average value was calculated.

### Evaluation Results

Table 7 shows the results of evaluating the controllability in the line width of the infrared pass filters and the absolute values of the difference values obtained by subtracting the second average value from the first average value for Test examples 2-1 to 2-16.

TABLE 7

| Pixel size | Line width | | | | Difference | 1st |
|---|---|---|---|---|---|---|
| (μm) | 2.0 | 1.8 | 1.6 | 1.4 | value (μm) | ratio |
| Test ex. 2-1 | good | good | good | good | 0.01 | 5.30 |
| Test ex. 2-2 | good | good | good | good | 0.02 | 5.30 |
| Test ex. 2-3 | good | good | good | good | 0.01 | 5.30 |
| Test ex. 2-4 | good | good | good | good | 0.02 | 5.30 |
| Test ex. 2-5 | good | good | good | good | 0.03 | 5.30 |
| Test ex. 2-6 | good | good | good | good | 0.03 | 5.30 |
| Test ex. 2-7 | good | good | good | good | 0.03 | 14.43 |
| Test ex. 2-8 | good | good | good | good | 0.03 | 29.15 |
| Test ex. 2-9 | good | good | good | good | 0.03 | 3.42 |
| Test ex. 2-10 | good | good | good | good | 0.03 | 5.30 |
| Test ex. 2-11 | good | good | good | good | 0.03 | 4.42 |
| Test ex. 2-12 | good | good | good | good | 0.03 | 4.42 |
| Test ex. 2-13 | poor | poor | poor | poor | 0.19 | 0.00 |
| Test ex. 2-14 | fair | fair | poor | poor | 0.11 | 1.18 |
| Test ex. 2-15 | fair | fair | fair | fair | 0.07 | 2.06 |
| Test ex. 2-16 | good | good | good | good | 0.01 | 41.22 |

As shown in Table 7, in Test examples 2-1 to 2-12 and 2-16, the controllability in the line width of the infrared pass filter was found to be “good” regardless of the pixel size. On the other hand, in Test example 2-13, the controllability in the line width of the infrared pass filter was found to be “poor” regardless of the pixel size. Further, in Test example 2-14, the controllability in the line width of the infrared pass filter was found to be “fair” or “poor”, and the smaller the pixel size, the lower the controllability in the line width of the infrared pass filter. In Test example 2-15, the controllability in the line width of the infrared pass filter was found to be “fair” regardless of the pixel size.

In addition, as shown in FIG. 3, when the first ratio was 3.42% or greater, the absolute values of the difference values obtained by subtracting the second average value from the first average value were found to be 0.03 μm or less. On the other hand, when the first ratio was 2.06% or less, the absolute values of the difference values obtained by subtracting the second average value from the first average value were found to be 0.07 or greater, and the amount of change in the absolute value in response to the change in the first ratio was found to be significantly large. From these results, it was found that the controllability in the line width of the infrared pass filter can be increased when the first ratio was 3.0% or greater.

### Evaluation of Rectangularity in Cross-Section

### Evaluation Method

For the test substrates of Test examples 2-1 to 2-16, the infrared pass filter of each pixel size was cut to expose the cross-section perpendicular to the surface of the silicon wafer. Specifically, the infrared pass filter exposed at the exposure amount at which the line width of the infrared pass filter was closest to the target line width was cut to expose the cross-section. The cross-section of the infrared pass filter of each pixel size was observed using a scanning electron microscope (manufactured by Hitachi High-Tech Corporation, S-4800). In the cross-section, the first width S at the first height 0.5H and the second width T at the second height 0.9H were measured. Then, the rectangularity, which was the ratio (T/S) of the second width T to the first width S, was calculated. The ratio of the second width T to the first width S was calculated for each pixel size in 20 infrared pass filters, and the average value of the ratios of the second width T to the first width S in the 20 infrared pass filters was set as the value of the ratio for each test example.

### Evaluation Results

Table 8 below shows the evaluation results of the rectangularity. In Table 8, the rectangularity was evaluated according to the following evaluation criteria.

Good: rectangularity T/S is 0.75 or more

Fair: rectangularity T/S is 0.7 or more and less than 0.75

Poor: rectangularity T/S is less than 0.7

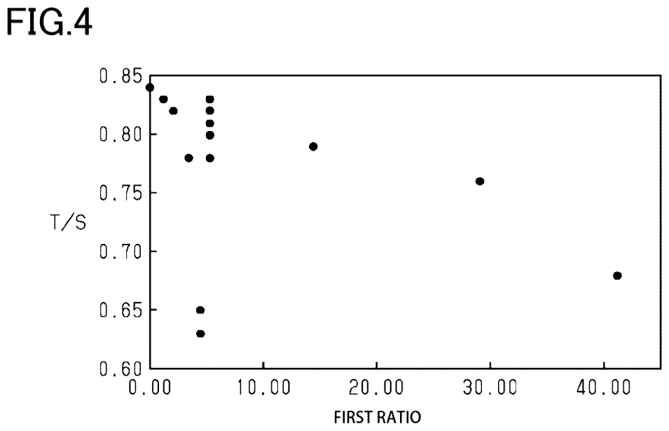

For each test example, the rectangularity when the pixel size was 1.4 μm was shown. In addition, FIG. 4 is a graph showing the relationship between the first ratio and the rectangularity when the pixel size was 1.4 μm.

TABLE 8

| Pixel size | T/S | | | | | 1st | 2nd |
|---|---|---|---|---|---|---|---|
| (μm) | 2.0 | 1.8 | 1.6 | 1.4 | | ratio | ratio |
| Test ex. 2-1 | good | good | good | good | 0.83 | 5.30 | 212.01 |
| Test ex. 2-2 | good | good | good | good | 0.81 | 5.30 | 212.01 |
| Test ex. 2-3 | good | good | good | good | 0.80 | 5.30 | 212.01 |
| Test ex. 2-4 | good | good | good | good | 0.82 | 5.30 | 212.01 |
| Test ex. 2-5 | good | good | good | good | 0.81 | 5.30 | 212.01 |
| Test ex. 2-6 | good | good | good | good | 0.82 | 5.30 | 212.01 |
| Test ex. 2-7 | good | good | good | good | 0.79 | 14.43 | 353.34 |
| Test ex. 2-8 | good | good | good | good | 0.76 | 29.15 | 412.23 |
| Test ex. 2-9 | good | good | good | good | 0.78 | 3.42 | 131.58 |
| Test ex. 2-10 | good | good | good | good | 0.78 | 5.30 | 212.01 |
| Test ex. 2-11 | fair | poor | poor | poor | 0.63 | 4.42 | 0.00 |
| Test ex. 2-12 | fair | fair | poor | poor | 0.65 | 4.42 | 2.95 |
| Test ex. 2-13 | good | good | good | good | 0.84 | 0.00 | 212.01 |
| Test ex. 2-14 | good | good | good | good | 0.83 | 1.18 | 212.01 |
| Test ex. 2-15 | good | good | good | good | 0.82 | 2.06 | 212.01 |
| Test ex. 2-16 | good | good | fair | poor | 0.68 | 41.22 | 212.01 |

As shown in Table 8, in Test examples 2-1 to 2-10 and 2-13 to 2-15, the rectangularity of the test substrate was found to be “good” regardless of the pixel size. On the other hand, in Test examples 2-11 and 2-12, the evaluation of the rectangularity was found to be “fair” or “poor” regardless of the pixel size. In Test examples 2-11 and 2-12, it was thought that the rectangularity of the infrared pass filter was low since the first ratio satisfied Condition 1 but the second ratio did not satisfy Condition 2. Further, in the test substrate of Test example 2-16, it was found that the smaller the pixel size, the lower the rectangularity of the infrared pass filter. In particular, the rectangularity was found to be “fair” when the pixel size was 1.6 μm, and the rectangularity was found to be “poor” when the pixel size was 1.4 μm. In Test example 2-16, it was thought that the rectangularity of the infrared pass filter was low since the second ratio satisfied Condition 2 but the first ratio did not satisfy Condition 1. In addition, as shown in FIG. 4, the rectangularity significantly decreased when the first ratio exceeded 30% compared with the case where the first ratio was 30% or less.

As described above, the following effects can be obtained by a coloring composition, a method of producing a coloring composition, and a method of producing an infrared pass filter according to embodiments of the present invention.
(1) It is possible to increase both rectangularity in the cross-section of the infrared pass filter 12P and controllability in the line width of the infrared pass filter 12P.
(2) The content of the first (meth)acrylate of 0.1 mass % or greater can accelerate polymerization reaction, increasing the rectangularity of the cross-section of the infrared pass filter 12P. The content of the first (meth)acrylate of 20 mass % or less can suppress a decrease in density of the colorant in the photosensitive coloring composition, preventing deterioration of the spectral properties of the infrared pass filter 12P.
(3) Due to the second (meth)acrylate being contained in the polymerizable compound, the sensitivity of the photosensitive coloring composition during exposure can be increased.
(4) The oxime ester-based photopolymerization initiator has high sensitivity to exposure light, and thus it is possible to reduce the content of the photopolymerization initiator in the photosensitive coloring composition.

Solid-state image sensors such as CMOS image sensors and CCD image sensors include photoelectric conversion elements that convert the intensity of light into an electrical signal. Solid-state image sensors include, in addition to the photoelectric conversion elements, color filters disposed on the photoelectric conversion elements for respective colors, and infrared pass filters disposed on the photoelectric conversion elements for infrared light.

The infrared pass filters block visible light that may otherwise be detected by the photoelectric conversion elements for infrared light to thereby improve detection accuracy of infrared light by the photoelectric conversion elements for infrared light. The infrared pass filters contain colorants. Examples of the colorants contained in the infrared pass filters include bisbenzofuranone-based pigments, azomethine-based pigments, perylene-based pigments and azo-based dyes (see e.g., JP 2016-177273 A and JP 2018-119077 A).

The solid-state image sensor includes repeating units which include photoelectric conversion elements for respective colors and a photoelectric conversion element for infrared light. In the repeating unit of the photoelectric conversion elements, the photoelectric conversion element for infrared light is adjacent to the photoelectric conversion elements for respective colors when viewed from the light-incident side of the solid-state image sensor. Accordingly, the repeating unit of the filters in the solid-state image sensor includes respective color filters and an infrared pass filter, and the infrared pass filter is adjacent to the respective color filters when viewed from the light-incident side of the solid-state image sensor.

From the viewpoint of preventing color mixture between the infrared pass filter and the respective color filters, the infrared pass filter is required to have high rectangularity in the cross-section perpendicular to a plane in which it extends. Further, from the viewpoint of preventing interference of the infrared pass filter with respective color filters and preventing a decrease in the light intensity of visible light passing through the infrared pass filter, high accuracy is required for the line width of the infrared pass filter as viewed in a direction perpendicular to a plane in which it extends.

Infrared pass filters are formed by photolithography on a coating film made of a coating liquid containing a photosensitive coloring composition. Therefore, in formation of infrared pass filters by photolithography, photosensitive compositions for infrared pass filters are required to achieve high rectangularity in the cross-section of the infrared pass filter and high controllability in the line width.

A photosensitive coloring composition for an infrared pass filter according to an embodiment of the present invention includes: a colorant; a polymerizable compound; a photopolymerization initiator; and a polymerization inhibitor. The polymerizable compound contains a first (meth)acrylate with two or more functional groups, at least one of the two or more functional groups being an amino group. A percentage of a mass of the first (meth)acrylate relative to a mass of the photopolymerization initiator is 50% or greater and 500% or less. A percentage of a mass of the polymerization inhibitor relative to a mass of the photopolymerization initiator is 3% or greater and 30% or less.

An infrared pass filter according to an embodiment of the present invention includes: a colorant; a polymerizable compound; a photopolymerization initiator; and a polymerization inhibitor. The polymerizable compound contains a first (meth)acrylate with two or more functional groups, at least one of the two or more functional groups being an amino group. A percentage of a mass of the first (meth)acrylate relative to a mass of the photopolymerization initiator is 50% or greater and 500% or less. A percentage of a mass of the polymerization inhibitor relative to a mass of the photopolymerization initiator is 3% or greater and 30% or less.

A method of producing a photosensitive coloring composition for an infrared pass filter, which includes a colorant, a polymerizable compound, a photopolymerization initiator and a polymerization inhibitor, according to an embodiment of the present invention includes mixing the colorant, the polymerizable compound, the photopolymerization initiator and the polymerization inhibitor. The polymerizable compound contains a first (meth)acrylate with two or more functional groups, at least one of the two or more functional groups being an amino group. A percentage of a mass of the first (meth)acrylate relative to a mass of the photopolymerization initiator is 50% or greater and 500% or less. A percentage of a mass of the polymerization inhibitor relative to a mass of the photopolymerization initiator is 3% or greater and 30% or less.

A method of producing an infrared pass filter according to an embodiment of the present invention includes: preparing a photosensitive coloring composition by the above method of producing a photosensitive coloring composition for an infrared pass filter; forming a coating film by applying a coating liquid containing the photosensitive coloring composition to an object to be coated; and curing the coating film.

Obviously, numerous modifications and variations of the present invention are possible in light of the above teachings. It is therefore to be understood that within the scope of the appended claims, the invention may be practiced otherwise than as specifically described herein.

1. A photosensitive coloring composition for an infrared pass filter, comprising:
a colorant;
a polymerizable compound;
a photopolymerization initiator; and
a polymerization inhibitor,
wherein the polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

2. The photosensitive coloring composition for an infrared pass filter according to claim 1, wherein a percentage of the first (meth)acrylate relative to a solid content mass of the photosensitive coloring composition for an infrared pass filter is in a range of 0.1% to 20%.

3. The photosensitive coloring composition for an infrared pass filter according to claim 1, wherein the polymerizable compound includes a second (meth)acrylate with three or more functional groups such that none of the three or more functional groups of the second (meth)acrylate is an amino group.

4. The photosensitive coloring composition for an infrared pass filter according to claim 1, wherein the photopolymerization initiator includes an oxime ester photopolymerization initiator.

5. The photosensitive coloring composition for an infrared pass filter according to claim 2, wherein the polymerizable compound includes a second (meth)acrylate with three or more functional groups such that none of the three or more functional groups of the second (meth)acrylate is an amino group.

6. The photosensitive coloring composition for an infrared pass filter according to claim 2, wherein the photopolymerization initiator includes an oxime ester photopolymerization initiator.

7. The photosensitive coloring composition for an infrared pass filter according to claim 3, wherein the photopolymerization initiator includes an oxime ester photopolymerization initiator.

8. The photosensitive coloring composition for an infrared pass filter according to claim 5, wherein the photopolymerization initiator includes an oxime ester photopolymerization initiator.

9. An infrared pass filter, comprising:
a colorant;
a polymerizable compound;
a photopolymerization initiator; and
a polymerization inhibitor,
wherein the polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

10. The infrared pass filter according to claim 9, wherein a percentage of the first (meth)acrylate relative to a solid content mass of the photosensitive coloring composition for an infrared pass filter is in a range of 0.1% to 20%.

11. The infrared pass filter according to claim 9, wherein the polymerizable compound includes a second (meth)acrylate with three or more functional groups such that none of the three or more functional groups of the second (meth)acrylate is an amino group.

12. The infrared pass filter according to claim 9, wherein the photopolymerization initiator includes an oxime ester photopolymerization initiator.

13. The infrared pass filter according to claim 10, wherein the polymerizable compound includes a second (meth)acrylate with three or more functional groups such that none of the three or more functional groups of the second (meth)acrylate is an amino group.

14. The infrared pass filter according to claim 10, wherein the photopolymerization initiator includes an oxime ester photopolymerization initiator.

15. The infrared pass filter according to claim 11, wherein the photopolymerization initiator includes an oxime ester photopolymerization initiator.

16. The infrared pass filter according to claim 13, wherein the photopolymerization initiator includes an oxime ester photopolymerization initiator.

17. A method of producing a photosensitive coloring composition for an infrared pass filter, comprising:
mixing a colorant, a polymerizable compound, a photopolymerization initiator, and a polymerization inhibitor,
wherein the polymerizable compound includes a first (meth)acrylate with two or more functional groups such that at least one of the two or more functional groups is an amino group and that a percentage of a mass of the first (meth)acrylate relative to a mass of the photopolymerization initiator is in a range of 50% to 500%, and a percentage of a mass of the polymerization inhibitor relative to a mass of the photopolymerization initiator is in a range of 3% to 30%.

18. The method of claim 17, wherein a percentage of the first (meth)acrylate relative to a solid content mass of the photosensitive coloring composition for an infrared pass filter is in a range of 0.1% to 20%.

19. The method of claim 17, wherein the polymerizable compound includes a second (meth)acrylate with three or more functional groups such that none of the three or more functional groups of the second (meth)acrylate is an amino group.

20. A method of producing an infrared pass filter, comprising:
preparing a photosensitive coloring composition by the method of claim 17;
applying a coating liquid comprising the photosensitive coloring composition to an object such that a coating film comprising the coating liquid is formed on the object; and
curing the coating film formed on the object.
